(19) United States
(12) Patent Application Publication
(10) Pub. No.: US 2022/0069008 A1
(43) Pub. Date: Mar. 3, 2022

(54) INTEGRATING STRUCTURE FOR CRYSTAL RESONATOR AND CONTROL CIRCUIT, AND INTEGRATING METHOD THEREFOR

(71) Applicant: NINGBO SEMICONDUCTOR INTERNATIONAL CORPORATION (SHANGHAI BRANCH), Shanghai (CN)

(72) Inventor: Xiaoshan QIN, Zhejiang (CN)

(21) Appl. No.: 17/419,579

(22) PCT Filed: Nov. 5, 2019
(86) PCT No.: PCT/CN2019/115652

§ 371 Date: Jun. 29, 2021

(30) Foreign Application Priority Data
Dec. 29, 2018 (CN) 201811647881.0

(51) Int. Cl. H01L 27/20; H03H 3/02; H03H 9/10; H03H 9/19

(52) U.S. Cl. CPC H01L 27/20; H03H 9/19; H03H 9/1042; H03H 3/02

(57) ABSTRACT

A structure and method for integrating a crystal resonator with a control circuit are disclosed. The crystal resonator is integrated with both the control circuit (110) and a semiconductor die (900) on a single device wafer (100) through forming a piezoelectric vibrator (500) on, and bonding the semiconductor die (900) to, a back side of the device wafer (100). This allows an increased degree of integration of the crystal resonator and on-chip modulation of its parameters. Compared with traditional crystal resonators, the disclosed crystal resonator is more compact in size and hence less power-consuming.

### TECHNICAL FIELD

The present invention relates to the field of semiconductor technology and, in particular, to a structure and method for integrating a crystal resonator with a control circuit.

### BACKGROUND

A crystal resonator is a device operating on the basis of inverse piezoelectricity of a piezoelectric crystal. As key components of crystal oscillators and filters, crystal resonators have been widely used to create high-frequency electrical signals for performing precise timing, frequency referencing, filtering and other frequency control functions that are necessary for measurement and signal processing systems.

The continuous development of semiconductor technology and increasing popularity of integrated circuits has brought about a trend toward miniaturization of various semiconductor components. However, existing crystal resonators are not only hard to be integrated with other semiconductor components and bulky themselves.

For example, common existing crystal resonators include surface-mount ones, in which a base is bonded with a metal solder (or an adhesive) to a cover to form a hermetic chamber in which a piezoelectric vibrator is housed. In addition, electrodes for the piezoelectric vibrator are electrically connected to an associated circuit via solder pads or wires. Further shrinkage of such crystal resonators is difficult, and their electrical connection to the associated integrated circuit by soldering or gluing additionally hinders the crystal resonators' miniaturization.

### SUMMARY OF THE INVENTION

It is an objective of the present invention to provide a method for integrating a crystal resonator with a control circuit, which overcomes the above described problems with conventional crystal resonators, i.e., a bulky size and difficult integration.

According to the present invention, the above objective is attained by a method for integrating a crystal resonator with a control circuit, including:

providing a device wafer having the control circuit formed therein;

forming, in the device wafer, a lower cavity with an opening at a back side of the device wafer;

forming a piezoelectric vibrator comprising a top electrode, a piezoelectric crystal and a bottom electrode on the back side of the device wafer in alignment with the lower cavity and forming a first connecting structure electrically connecting the top and bottom electrodes of the piezoelectric vibrator to the control circuit;

forming a cap layer over the back side of the device wafer, which hoods the piezoelectric vibrator and delimits an upper cavity of the crystal resonator together with the piezoelectric vibrator and the device wafer; and

bonding a semiconductor die to the back side of the device wafer and forming a second connecting structure electrically connecting the semiconductor die to the control circuit.

It is another objective of the present invention to provide a structure for integrating a crystal resonator with a control circuit, including:

a device wafer in which the control circuit and a lower cavity are formed, the lower cavity having an opening at a back side of the device wafer;

a piezoelectric vibrator comprising a bottom electrode, a piezoelectric crystal and a top electrode, the piezoelectric vibrator formed on the back side of the device wafer in alignment with the lower cavity;

a first connecting structure formed on the device wafer, the first connecting structure electrically connecting the top and bottom electrodes of the piezoelectric vibrator to the control circuit;

a cap layer formed on the back side of the device wafer, the cap layer hooding the piezoelectric vibrator, the cap layer delimiting an upper cavity together with the piezoelectric vibrator and the device wafer;

a semiconductor die bonded to the back side of the device wafer; and

a second connecting structure electrically connecting the semiconductor die to the control circuit.

In the proposed method, planar fabrication processes are utilized to form the lower cavity in the device wafer containing the control circuit and expose the lower cavity at the back side of the device wafer. As a result, the piezoelectric vibrator is allowed to be formed on the same back side in alignment with the lower cavity resulting in the formation of the crystal resonator. Moreover, the semiconductor die is bonded to the back side of the device wafer, achieving the integration of the crystal resonator with both the control circuit and the semiconductor die.

Therefore, in addition to a greatly increased degree of integration resulting from the integration with the control circuit and crystal resonator on the same semiconductor substrate, the proposed crystal resonator has improved performance because it allows on-chip modulation of parameters (e.g., for correcting raw deviations such as temperature and frequency drifts). Compared with traditional crystal resonators (e.g., surface-mount ones), the crystal resonator fabricated using the proposed method is more compact, miniaturized in size, less costly and less power-consuming.

### BRIEF DESCRIPTION OF THE DRAWINGS

FIG. 1 shows a flowchart schematically illustrating a method for integrating a crystal resonator with a control circuit according to an embodiment of the present invention.

FIGS. 2a to 2n are schematic representations of structures resulting from steps in a method for integrating a crystal resonator with a control circuit according to an embodiment of the present invention.

FIG. 3 is a schematic illustration of a structure for integrating a crystal resonator with a control circuit according to an embodiment of the present invention.

In these figures,

100—device wafer; AA—device area; 100U—front side; 100D—back side; 100A—substrate wafer; 1100B—dielectric layer; 101—base layer; 102—buried oxide layer; 103—top silicon layer; 110—control circuit; 111—first circuit; 111a—first interconnect; 111b—third interconnect; 112—second circuit; 112a—second interconnect; 112b—fourth interconnect; 120—lower cavity; 211b—third conductive plug; 212b—fourth conductive plug; 211a—first conductive plug; 212a—second conductive plug; 221b—third connecting wire; 222b—fourth connecting wire; 221a—first connecting wire; 222a—second connecting wire; 300—planarized layer; 400—support wafer; 500—piezoelectric vibrator; 510—bottom electrode; 520—piezoelectric crystal; 530—top electrode; 600—plastic encapsulation layer; 610—fifth conductive plug; 700—upper cavity; 710—sacrificial layer; 720—cap layer; 720a—opening; 730—closure plug; 800—plastic encapsulation layer; 900—semiconductor die; 910—first contact pad; 920—second contact pad.

### DETAILED DESCRIPTION

The core idea of the present invention is to provide a structure and method for integrating a crystal resonator with a control circuit, in which planar fabrication processes are utilized to integrate a piezoelectric vibrator on a substrate where the control circuit is formed. This, on the one hand, results in a size reduction of the crystal resonator and, on the other hand, allows integration of the crystal resonator with other semiconductor components with an increased degree of integration.

Specific embodiments of the proposed structure and method will be described below in greater detail with reference to the accompanying drawings. Features and advantages of the invention will be more apparent from the following description. Note that the accompanying drawings are provided in a very simplified form not necessarily drawn to exact scale and for the only purpose of helping to explain the disclosed embodiments in a more convenient and clearer way.

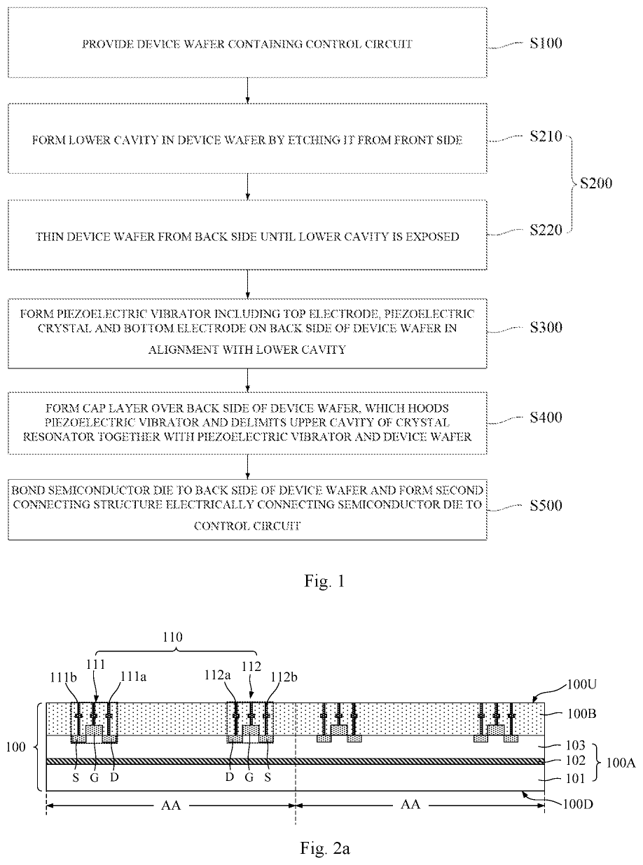

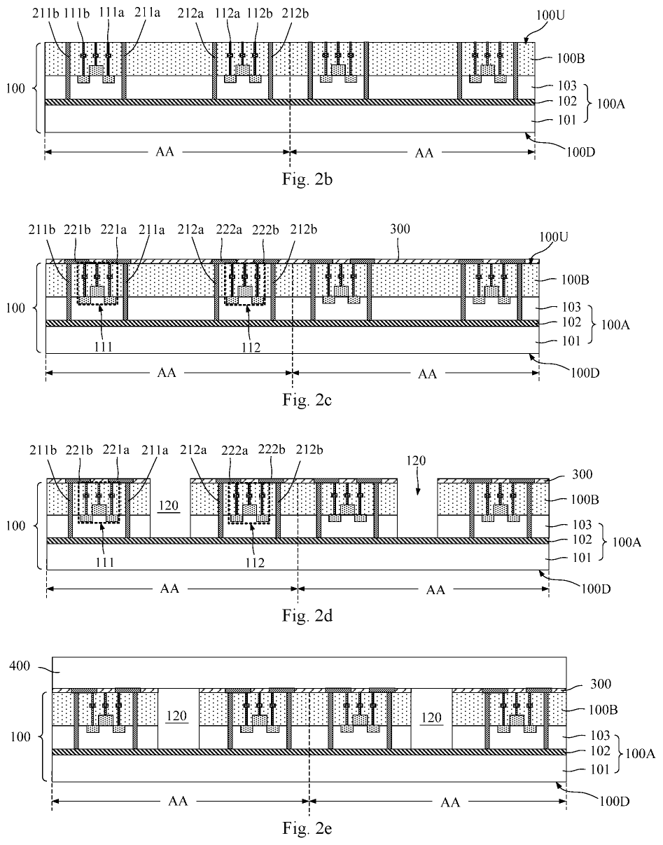

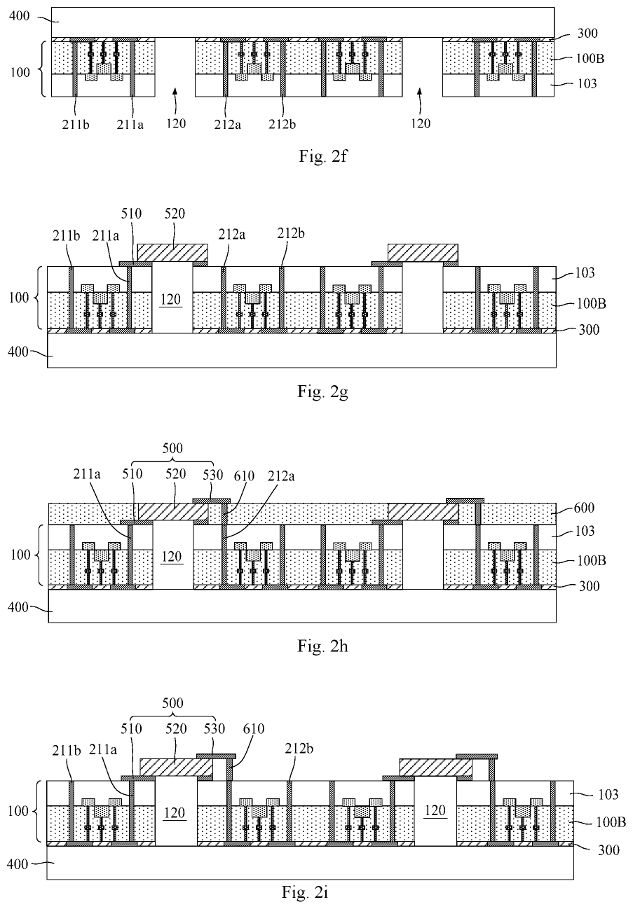

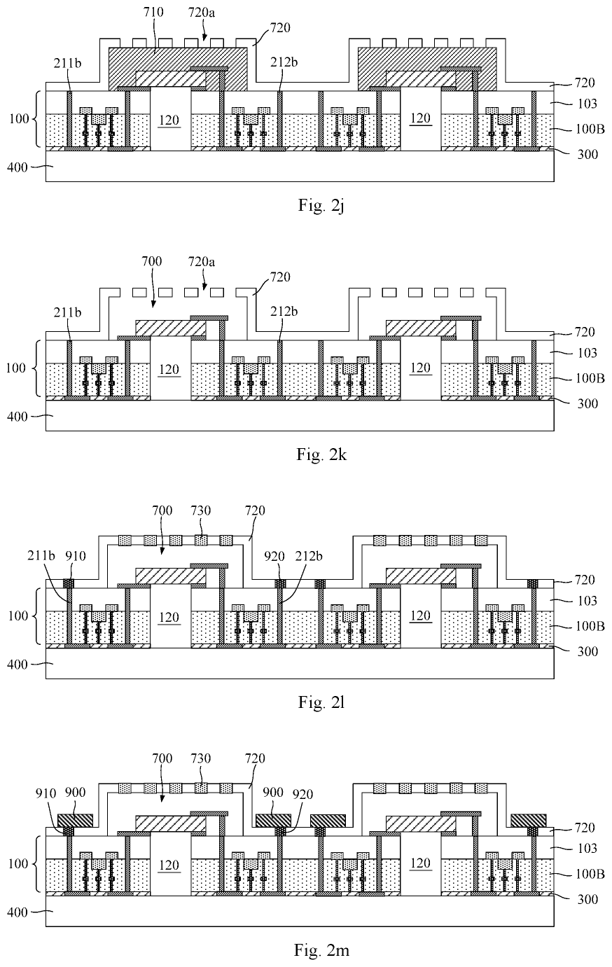

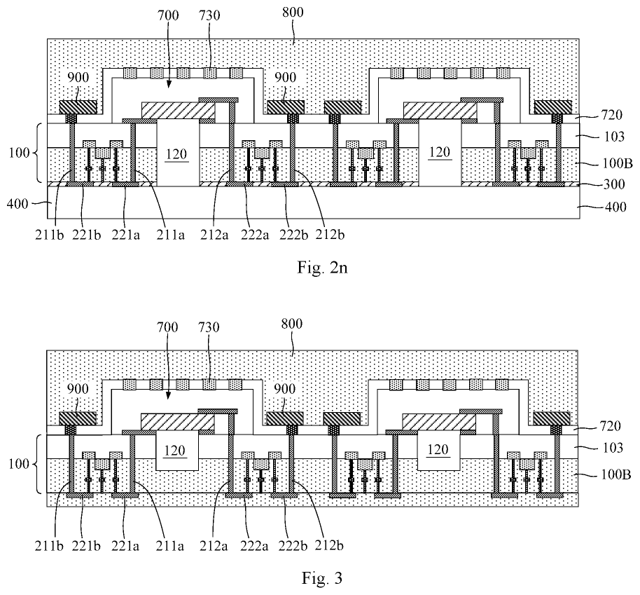

FIG. 1 shows a flowchart schematically illustrating a method for integrating a crystal resonator with a control circuit according to an embodiment of the present invention, and FIGS. 2a to 2n are schematic representations of structures resulting from steps in the method for integrating a crystal resonator with a control circuit according to an embodiment of the present invention. In the following, steps for forming the crystal resonator will be described in detail with reference to the figures.

In step S100, with reference to FIG. 2a, a device wafer 100 is provided, and a control circuit 110 is formed in the device wafer 100.

Specifically, the device wafer 100 has a front side 100U and a back side 100D opposite to the front side, and the control circuit 110 includes a plurality of interconnects, at least some of which extend to the front side 100U of the device wafer, and the extension is exposed at the front side 100U of the device wafer 100. The control circuit 110 may be adapted to, for example, apply an electrical signal to a subsequently formed piezoelectric vibrator.

A plurality of crystal resonators may be formed on the single device wafer 100. Accordingly, there may be a plurality of device areas AA defined on the device wafer 100, with the control circuit 110 being formed in one of the device areas AA.

The control circuit 110 may include a first circuit 111 and a second circuit 112, the first circuit 111 and the second circuit 112 may be electrically connected to a top electrode and a bottom electrode of the subsequently formed piezoelectric vibrator, respectively.

With continued reference to FIG. 2a, the first circuit 111 may include a first transistor, a first interconnect 111a and a third interconnect 111b. The first transistor may be buried within the device wafer 100, and the first and third interconnect 111a, 111b may be both connected to the first transistor and extend to the front side of the device wafer. For example, the first interconnect 111a may be connected to a drain of the first transistor, and the third interconnect 111b to a source of the first transistor.

Similarly, the second circuit 112 may include a second transistor, a second interconnect 112a and a fourth interconnect 112b. The second transistor may be buried within the device wafer 100, and the second and fourth interconnects 112a, 112b may be both connected to the second transistor and extend to the front side 100U of the device wafer 100. For example, the second interconnect 112a may be connected to a drain of the second transistor, and the fourth interconnect 112b may be connected to a source of the second transistor.

In this embodiment, the device wafer 100 includes a substrate wafer 100A and a dielectric layer 100B on the substrate wafer 100A. The front side 100U may be provided by a surface of the dielectric layer 100B facing away from the substrate wafer 100A. Additionally, the first and second transistors may be both formed on the substrate wafer 100A and covered by the dielectric layer 100B. The third, first, second and fourth interconnects 111b, 111a, 112a, 112b may be all formed within the dielectric layer 100B and extend to the surface of the dielectric layer 100B facing away from the substrate wafer.

The substrate wafer 100A may be either a silicon wafer or a silicon-on-insulator (SOI) wafer. In this embodiment, the substrate wafer 100A is an SOI wafer including a base layer 101, a buried oxide layer 102 and a top silicon layer 103, which are sequentially stacked in this order in the direction from the back side 100D to the front side 100U. In this embodiment, both the first and second transistors are formed in the top silicon layer 103 under the buried oxide layer 102.

It is to be noted that, in this embodiment, the interconnects in the control circuit extend to the front side 100U of the device wafer, while the piezoelectric vibrator is to be subsequently formed on, and the semiconductor die is to be subsequently bonded to, the back side 100D of the device wafer. Accordingly, a first connecting structure may be subsequently formed to lead connection ports of the control circuit 110 for electrically connecting the piezoelectric vibrator from the front to back side of the device wafer and brought into electrical connection with the subsequently formed piezoelectric vibrator there. Moreover, a second connecting structure may be formed to lead connection ports of the control circuit 110 for electrically connecting the semiconductor die from the front to back side of the device wafer.

Specifically, the first connecting structure may include a first connection and a second connection, the first connection is configured for electrically connecting the first interconnect 111a to the bottom electrode of the subsequently formed piezoelectric vibrator and the second connection is configured for electrically connecting the second interconnect 112a to the top electrode of the subsequently formed piezoelectric vibrator.

In the first connecting structure, the first connection may include a first conductive plug 211a configured for electrical connection at its opposing ends respectively to the first interconnect 111a and the subsequently formed bottom electrode. That is, the first conductive plug 211a may serve to lead a connecting port of the first interconnect 111a in the control circuit from a front side of the control circuit to a back side of the control circuit so as to enable electrical connection of the bottom electrode subsequently formed on the back side of the device wafer to the control circuit from the back side of the control circuit.

Optionally, in this embodiment, the first connection may further include a first connecting wire 221a formed, for example, on the front side of the device wafer. The first connecting wire 221a may connect one end of the first conductive plug 211a to the first interconnect, and the other end of the first conductive plug 211a may be electrically connected to the bottom electrode.

In alternative embodiments, the first connecting wire in the first connection may be formed on the back side of the device wafer. In this case, the first connecting wire may connect one end of the first conductive plug 211a to the bottom electrode, and the other end of the first conductive plug 211a may be electrically connected to the first interconnect in the control circuit.

Similarly, the second connection may include a second conductive plug 212a configured for electrical connection at its opposing ends respectively to the second interconnect 112a and the subsequently formed top electrode. That is, the second conductive plug 212a may serve to lead a connecting port of the second interconnect 112a in the control circuit from the front to back side of the control circuit so as to enable electrical connection of the top electrode subsequently formed on the back side of the device wafer to the control circuit from the back side of the control circuit.

Additionally, in this embodiment, the second connection may further include a second connecting wire 222a formed, for example, on the front side of the device wafer. The second connecting wire 222a may connect one end of the second conductive plug 212a to the second interconnect, and the other end of the second conductive plug 212a may be electrically connected to the top electrode.

In alternative embodiments, the second connecting wire in the second connection may be formed on the back side of the device wafer. In this case, the second connecting wire may connect one end of the second conductive plug 212a to the top electrode, and the other end of the second conductive plug 212a may be electrically connected to the second interconnect in the control circuit.

The first conductive plug 211a in the first connection and the second conductive plug 212a in the second connection may be formed in a single process step. The first connecting wire 221a in the first connection and the second connecting wire 222a in the second connection may also be formed in a single process step.

The second connecting structure may also include conductive plugs and connecting wires. Likewise, the conductive plugs in the second connecting structure may extend through the device wafer, and the connecting wires in the second connecting structure may be formed, for example, on the front side of the device wafer and connect the conductive plugs to the control circuit. As such, the conductive plugs and connecting wires in the second connecting structure can lead connection ports of the control circuit for connecting the semiconductor die from the front to back side of the device wafer. In this embodiment, the conductive plugs in the second connecting structure may include a third conductive plug 211b and a fourth conductive plug 212b, and the connecting wires in the second connecting structure may include a third connecting wire 221b and a fourth connecting wire 222b.

The first conductive plug 211a and the first connecting wire 221a in the first connection, the second conductive plug 212a and the second connecting wire 222a in the second connection, and the third conductive plug 211b, the third connecting wire 221b, the fourth conductive plug 212b and the fourth connecting wire 222b in the second connecting structure may be formed in a single process including, for example, the steps as follows:

Step 1: Etch the device wafer 100 from the front side 100U of the device wafer 100 so that a first connecting hole, a second connecting hole, a third connecting hole and a fourth connecting hole are formed, as shown in FIG. 2b. Specifically, all the first, second, third and fourth connecting holes may have a bottom that is closer to the back side 100D of the device wafer than a bottom of the control circuit.

Step 2: Fill a conductive material in the first, second, third and fourth connecting holes, resulting in the formation of the first, second, third and fourth conductive plugs 211a, 212a, 211b, 212b, as also shown in FIG. 2b.

In this way, all the first, second, third and fourth conductive plugs 211a, 212a, 211b, 212b are located at the bottom closer to the back side 100D of the device wafer than the control circuit. As a result, the first, second, third and fourth conductive plugs 211a, 212a, 211b, 212b all extend from the front side of the control circuit 110 to the back side of the control circuit 110.

Specifically, the first and second transistors 111T, 112T may be both formed within the top silicon layer 103 above the buried oxide layer 102, while the first, second, third and fourth conductive plugs 211a, 212a, 211b, 212b may each penetrate sequentially through the dielectric layer 100B and the top silicon layer 103 and terminate at the buried oxide layer 102. Thus, it may be considered that the buried oxide layer 102 can serve as an etch stop layer for the etching process for forming the first, second, third and fourth connecting holes. In this way, high etching accuracy can be achieved for the etching process.

In a subsequent process, the device wafer may be thinned from the back side so that the first, second, third and fourth conductive plugs 211a, 212a, 211b, 212b are exposed from the processed back side and brought into electrical connection with the piezoelectric vibrator and semiconductor die on the back side.

Step 3: Form the first connecting wire 221a, the second connecting wire 222a, the third connecting wire 221b and the fourth connecting wire 222b on the front side of the device wafer 100, the first connecting wire 221a connects the first conductive plug 211a to the first interconnect 111a, the second connecting wire 222a connects the second conductive plug 212a to the second interconnect 112a, the third connecting wire 221b connects the third conductive plug 211b to the third interconnect 111b, and the fourth connecting wire 222b connects the fourth conductive plug 212b to the fourth interconnect 112b, as shown in FIG. 2c.

In embodiments with the first connecting wire in the first connection, the second connecting wire in the second connection and the connecting wires in the second connecting structure being all formed on the back side of the device wafer, the formation of the first connection that includes the first conductive plug and the first connecting wire, of the second connection that includes the second conductive plug and the second connecting wire and of the second connecting structure may include, for example:

first, forming a first connecting hole, a second connecting hole, a third connecting hole and a fourth connecting hole by etching the device wafer from the front side of the device wafer;

then forming the first, second, third and fourth conductive plugs by filling a conductive material into the first, second, third and fourth connecting holes, the first conductive plug is electrically connected to the first interconnect, the second conductive plug is electrically connected to the second interconnect, the third conductive plug is electrically connected to the third interconnect and the fourth conductive plug is electrically connected to the fourth interconnect;

subsequently, thinning the device wafer from the back side of the device wafer so that the first, second, third and fourth conductive plugs are exposed; and

forming the first, second, third and fourth connecting wires on the back side of the device wafer, the first connecting wire is connected to the first conductive plug at one end and configured for electrical connection with the bottom electrode at the other end, the second connecting wire is connected to the second conductive plug at one end and configured for electrical connection with the top electrode at the other end, the third connecting wire is connected to the third conductive plug at one end and configured for electrical connection with the semiconductor die at the other end, and the fourth connecting wire is connected to the fourth conductive plug at one end and configured for electrical connection also with the semiconductor die at the other end.

It is to be noted that although the first, second, third and fourth conductive plugs 211a, 212a, 211b, 212b have been described above as being formed from the front side of the device wafer prior to the formation of the first, second, third and fourth connecting wires 221a, 222a, 221b, 222b, they may alternatively formed from the back side of the device wafer subsequent to the thinning of the device wafer, as will be described in greater detail below.

In addition, in a subsequent process, a support wafer may be bonded to the front side 100U of the device wafer 100. According, subsequent to the formation of the first, second, third and fourth connecting wires 221a, 222a, 221b, 222b, the method may optionally further include forming, on the front side 100U of the device wafer 100, a planarized layer 300 which provides the device wafer 100 with a flatter bonding surface.

Specifically, referring to FIG. 2c, the planarized layer 300 may be formed on the front side 100U of the device wafer 100, and the surface of the planarized layer 300 facing away from the device wafer 100 may be not lower than that of a rewiring layer (including the first, second, third and fourth connecting wires 221a, 222a, 221b, 222b, for example). For example, the planarized layer 300 may cover the device wafer 100 and the rewiring layer so that the surface of the planarized layer 300 facing away from the device wafer 100 provides the device wafer 100 with a flat bonding surface. Alternatively, the surface of the planarized layer 300 may be flush with that of the rewiring layer, and this can also achieve the purpose of providing the device wafer 100 with a flat bonding surface.

In this embodiment, the planarized layer 300 may be formed using a polishing process. In this case, for example, the rewiring layer may serve as a polish stop such that the top surface of the formed planarized layer 300 is flush with those of the first, second, third and fourth connecting wires 221a, 222a, 221b, 222b, and all these surfaces may form a bonding surface for the device wafer 100.

In step S200, with reference to FIGS. 2c to 2f, a lower cavity 120 with an opening at the back side of the device wafer is formed in the device wafer 100.

In this embodiment, the lower cavity 120 may be formed, for example, using a method including steps S210 and S220 below.

In step S210, with reference to FIG. 2c, the lower cavity 120 of the crystal resonator is formed by etching the device wafer 100 from the front side of the device wafer 100.

Specifically, the lower cavity 120 extends deep into the device wafer 100 from the front side 100U and may have a bottom that is closer to the back side 100D of the device wafer than the bottom of the control circuit 110.

In this embodiment, the lower cavity 120 may be formed by performing an etching process which proceeds sequentially through the planarized layer 300, the dielectric layer 100B and the top silicon layer 103 and stops at the buried oxide layer 102.

Thus, the buried oxide layer 102 may serve as an etch stop layer for both the etching process for forming the first, second, third and fourth connecting holes for the first, second, third and fourth conductive plugs 211a, 212a, 211b, 212b and the etching process for forming the lower cavity 120. As a result, bottoms of the resulting conductive plugs are at the same or similar level as that of the lower cavity 120. In this way, it can be ensured that the first, second, third and fourth conductive plugs 211a, 212a, 211b, 212b and the lower cavity 120 can be all exposed when the device wafer is subsequently thinned from the back side 100D of the device wafer 100.

It is to be noted that the relative positions of the lower cavity 120 and the first and second circuits shown in the figures are merely for illustration, and in practice, the arrangement of the first and second circuits may depend on the actual circuit layout requirements, without limiting the present invention.

In step S220, with reference to FIGS. 2e and 2f, the device wafer 100 is thinned from the back side 100D of the device wafer 100 until the lower cavity 120 is exposed.

As noted above, the lower cavity 120 is bottomed at the buried oxide layer 102. Therefore, as a result of thinning the device wafer, the base layer 101 and the buried oxide layer 102 are sequentially removed, and the top silicon layer 103 and the lower cavity 120 are both exposed. Moreover, in this embodiment, since the first, second, third and fourth conductive plugs 211a, 212a, 211b, 212b are all also bottomed at the buried oxide layer 102, the thinning of the device wafer also results in the exposure of the first, second, third and fourth conductive plugs 211a, 212a, 211b, 212b, which allows these conductive plugs to be brought into electrical connection to the subsequently formed piezoelectric vibrator and to the semiconductor die.

Optionally, with reference to FIG. 2d, before the device wafer 100 is thinned, a support wafer 400 may be bonded to the front side of the device wafer 100, which can provide a support for the thinning process. Additionally, the support wafer 400 can close the opening of the lower cavity exposed at the front side of the device wafer. Therefore, it can be considered that, in this embodiment, the support wafer 400 also serves as a cap substrate for closing the opening of the lower cavity at the front side of the device wafer.

It is to be noted that, in this embodiment, the lower cavity 120 is formed by etching the device wafer 100 from the front side and thinning the device wafer 100 from the back side so that the opening of the lower cavity 120 is exposed at the back side of the device wafer 100.

However, referring to FIG. 3, in other embodiments, the lower cavity 120 of the crystal resonator may be alternatively formed by etching the device wafer from the back side. In still other embodiments, the etching process on the back side of the device wafer may be preceded by a thinning of the device wafer.

With particular reference to FIG. 3, in one specific embodiment, the formation of the lower cavity by etching the device wafer from the back side thereof may include, for example, the following steps.

At first, the device wafer is thinned from the back side thereof. In case of the substrate wafer being an SOI wafer, this may involve sequential removal of the base layer and the buried oxide layer of the substrate wafer. Of course, the thinning of the substrate wafer may alternatively involve partial removal of the base layer, complete removal of the base layer and hence exposure of the buried oxide layer, or the like.

Next, the buried oxide layer is etched from the back side of the device wafer so that the lower cavity is formed. It is to be noted that the lower cavity resulting from the etching of the device wafer may have a depth as practically required, and the present invention is not limited to any particular depth of the lower cavity. For example, after the device wafer is thinned and the top silicon layer 103 is exposed, the top silicon layer 103 may be etched to form the lower cavity therein. Alternatively, the etching process may proceed through the top silicon layer 103 and further into the dielectric layer 100B, so that the resulting lower cavity 120 extends from the top silicon layer 103 down into the dielectric layer 100B.

It is to be also noted that during the formation of the lower cavity as shown in FIG. 3, prior to the formation of the lower cavity, another support wafer may be optionally bonded to the front side of the device wafer to enhance support for the device wafer. Of course, instead of bonding the support wafer, it is also plausible to form a plastic encapsulation layer on the front side of the device wafer, which covers all the components exposed on the front side of the device wafer.

As discussed above, in other embodiments, the thinning of the device wafer may be followed by forming the first conductive plug 211a in the first connection, the second conductive plug 212a in the second connection and the third and fourth conductive plugs 211b, 212b in the second connecting structure from the back side of the device wafer 100.

Specifically, a method for forming the aforementioned connecting wires on the front side of the device wafer 100, forming the above conductive plugs from the back side of the device wafer 100, and connecting the conductive plugs to the respective connecting wires may include the steps below.

At first, prior to the bonding of the support wafer 400, the first, second, third and fourth connecting wires 221a, 222a, 221b, 222b are formed on the front side of the device wafer 100.

Wherein, the first connecting wire 221a is electrically connected to the first interconnect 111a, the second connecting wire 212a to the second interconnect 112a, the third connecting wire 221b to the third interconnect 111b and the fourth connecting wire 212b to the fourth interconnect 112b.

Next, after the device wafer 100 is thinned, the device wafer 100 is etched from the back side thereof to form therein first, second, third and fourth connecting holes, all of which extend through the device wafer 100 so that the first, second, third and fourth connecting wires 221a, 222a, 221b, 222b are exposed respectively in the first, second, third and fourth connecting holes.

Subsequently, a conductive material is filled in the first, second, third and fourth connecting holes, resulting in the formation of the first, second, third and fourth conductive plugs 211a, 212a, 211 b, 212b.

Wherein, the first conductive plug 211a is connected at one end to the first connecting wire 221a and configured for electrical connection with the bottom electrode of the piezoelectric vibrator at the other end. The second conductive plug 212a is connected at one end to the second connecting wire 222a and configured for electrical connection with the top electrode of the piezoelectric vibrator at the other end. The third conductive plug 211b is connected at one end to the third connecting wire 221b and configured for electrical connection with the semiconductor die at the other end. The fourth conductive plug 212b is connected at one end to the fourth connecting wire 222b and configured for electrical connection also with the semiconductor die at the other end.

In an alternative embodiment, a method for forming the aforementioned connecting wires on the back side of the device wafer 100, forming the above conductive plugs from the back side of the device wafer 100, and connecting the conductive plugs to the respective connecting wires may include the steps below.

At first, the device wafer 100 is thinned from the back side of the device wafer 100, followed by etching the device wafer 100 from the back side and thus forming first, second, third and fourth connecting holes.

Next, a conductive material is filled in the first, second, third and fourth connecting holes, resulting in the formation of the first, second, third and fourth conductive plugs. The first conductive plug is electrically connected at one end to the first interconnect, and the second conductive plug is electrically connected at one end to the second interconnect. The third conductive plug is electrically connected at one end to the third interconnect, and the fourth conductive plug is electrically connected at one end to the fourth interconnect.

Subsequently, the first, second, third and fourth connecting wires are formed on the back side of the device wafer 100. One end of the first connecting wire is connected to the other end of the first conductive plug, and the other end of the first connecting wire is configured for electrical connection with the bottom electrode. One end of the second connecting wire is connected to the other end of the second conductive plug, and the other end of the second connecting wire is configured for electrical connection with the top electrode. One end of the third connecting wire is connected to the other end of the third conductive plug, and the other end of the second connecting wire is configured for electrical connection with the semiconductor die. One end of the fourth connecting wire is connected to the other end of the fourth conductive plug, and the other end of the fourth connecting wire is configured for electrical connection also with the semiconductor die.

In step S300, with reference to FIGS. 2g to 2i, a piezoelectric vibrator 500 including a top electrode 530, a piezoelectric crystal 520 and a bottom electrode 510 is formed on the back side of the device wafer 100 (i.e., the surface of the device wafer 100 facing away from the support wafer 400). The formed piezoelectric vibrator 500 is so aligned with the lower cavity 120 that the peripheral edge portions of the piezoelectric vibrator 500 resting on top edges of the lower cavity 120.

Specifically, the formation of the piezoelectric vibrator 500 may include, for example, the steps as follows:

Step 1: Form the bottom electrode 510 at a predetermined location on the back side of the device wafer 100 (i.e., the surface facing away from the support wafer 400), as shown in FIG. 2g. In this embodiment, the bottom electrode 510 surrounds the lower cavity 120 and covers the first conductive plug 211a. As a result, the bottom electrode 510 is electrically connected to the first circuit 111 and hence to the first transistor via the first conductive plug 211a.

The bottom electrode 510 may be formed of, for example, silver, and the formation of the bottom electrode 510 may involve successive processes of thin-film deposition, photolithography and etching. Alternatively, the bottom electrode 510 may be formed using a vapor deposition process.

Step 2: With continued reference to FIG. 2g, bond the piezoelectric crystal 220 to the bottom electrode 210, so that the piezoelectric crystal 520 is located above the lower cavity 120, with its peripheral edge portions residing on portions of the bottom electrode 510 around top edges of the lower cavity 120. As such, the piezoelectric crystal 520 is aligned with the lower cavity 120. The piezoelectric crystal 520 may be, for example, a quartz crystal plate.

Step 3: Form the top electrode 530 on the piezoelectric crystal 520, as shown in FIG. 2h. As with the bottom electrode 510, the top electrode 530 may also be formed of, for example, silver, using a vapor deposition process or thin-film deposition process. The top electrode 530 may be brought into electrical connection with the control circuit in a subsequent process.

Notably, in this embodiment, the bottom electrode 510, the piezoelectric crystal 520 and the top electrode 530 are successively formed over the device wafer 100 using semiconductor processes. However, in other embodiments, it is also possible to form the top and bottom electrodes on opposing sides of the piezoelectric crystal and then bond the three as a whole onto the device wafer 100.

As noted above, in the resulting piezoelectric vibrator 500, the bottom electrode 510 is electrically connected to the first circuit via the first connection, and the top electrode 530 is electrically connected to the second circuit via the second connection.

Thus, the piezoelectric vibrator 500 is electrically connected to the control circuit 110 from the back side of the control circuit 110, allowing the control circuit 110 to apply an electrical signal to the bottom and top electrodes 510, 530 of the piezoelectric vibrator 500 to form an electric field between the bottom electrode 510 and the top electrode 530, which causes the piezoelectric crystal 520 of the piezoelectric vibrator 500 to change its shape. When the electric field in the piezoelectric vibrator 500 is inverted, the piezoelectric crystal 520 will responsively change its shape in the opposite direction. Therefore, when the control circuit 110 applies an AC signal to the piezoelectric vibrator 500, the piezoelectric crystal 520 will change shape alternately in opposite directions and thus alternately contract and expand due to oscillations of the electric field. As a result, the piezoelectric crystal 520 will vibrate mechanically.

In case of the first connection including the first conductive plug 211a and the first connecting wire 221a, the bottom electrode 510 may extend beyond the piezoelectric crystal 520 thereunder over the first conductive plug 211a, thus the bottom electrode 510 coming into electrical connection with the control circuit via the first connection.

With continued reference to FIG. 2h, in addition to the second conductive plug 212a and the second connecting wire 222a, the second connection may further include a fifth conductive plug 610, the fifth conductive plug 610 is connected to the second conductive plug 212a at the bottom and to the top electrode 530 at the top while providing the top electrode 530 with support.

Specifically, the formation of fifth conductive plug 610 in the second connection and of the top electrode 530 may include the steps below.

First of all, with reference to FIG. 2h, prior to the formation of the top electrode, a plastic encapsulation layer 600 is formed over the back side of the device wafer 100, the plastic encapsulation layer 600 covers the device wafer 100, with the piezoelectric crystal 520 being exposed therefrom. Exemplary materials for the plastic encapsulation layer 600 may include, for example, polyimide.

Next, with continued reference to FIG. 2h, a through hole is formed in the plastic encapsulation layer 600. In this embodiment, the through hole extends through the plastic encapsulation layer 600 so that the second conductive plug 212a is exposed in the hole.

Subsequently, a conductive material is filled in the through hole, resulting in the formation of the fifth conductive plug 610, the fifth conductive plug 610 is electrically connected to the second conductive plug 212a at the bottom and exposed from the plastic encapsulation layer 600 at the top.

Thereafter, with continued reference to FIG. 2h, the top electrode 530 is formed on the piezoelectric crystal 520, the top electrode 530 extends from the piezoelectric crystal 520 to the plastic encapsulation layer 600 so as to extend over the fifth conductive plug 610 and thus the top electrode 530 come into electrical connection with the second conductive plug 212a via the fifth conductive plug 610.

Afterward, with reference to FIG. 2i, the plastic encapsulation layer 600 is removed.

It is to be noted that in embodiments with the second connecting wire in the second connection being formed on the back side of the device wafer, the third conductive plug of the second connection may be brought into electrical connection with the second connecting wire at the top.

Of course, in alternative embodiments, in addition to the second connecting wire 222a, the second conductive plug 212a and the fifth conductive plug, the second connection may further include an interconnecting wire. In such embodiments, the fifth conductive plug may be connected to the second conductive plug 212a at the bottom and to one end of the interconnecting wire at the top, and the other end of the interconnecting wire may overlap at least part of the top electrode 530 and thus come into electrical connection with the top electrode 530.

Specifically, in these embodiments, the formation of the fifth conductive plug and the interconnecting wire may include, for example, the steps below.

At first, a plastic encapsulation layer is formed over the surface of the device wafer 100 facing away from the support wafer 400. The plastic encapsulation layer may be formed subsequent to the formation of the top electrode in such a manner that the top electrode 530 is exposed from the plastic encapsulation layer.

Next, a through hole is formed in the plastic encapsulation layer, which extends through the plastic encapsulation layer to the back side of the device wafer so that the second conductive plug 212a is exposed in the hole, and a conductive material is filled in the through hole to result in the formation of the fifth conductive plug that is electrically connected at the bottom to second conductive plug 212a.

Subsequently, the interconnecting wire is formed on the plastic encapsulation layer. The interconnecting wire covers at least part of the top electrode 530 and extends from the top electrode 530 over the fifth conductive plug. The plastic encapsulation layer is then removed. Thus, the top electrode 530 is electrically connected to the second conductive plug 212a via the interconnecting wire and the fifth conductive plug.

In step S400, with reference to FIGS. 2j to 2k, a cap layer 720 is formed over the back side of the device wafer 100, the cap layer 720 hoods the piezoelectric vibrator 500 and delimits an upper cavity 700 of the crystal resonator together with the piezoelectric vibrator 500 and the device wafer 100.

Specifically, the formation of the cap layer 420 that delimits the upper cavity 400 may include, for example, the steps below.

In a first step, with reference to FIG. 2j, a sacrificial layer 710 is formed on the surface of the device wafer 100, the sacrificial layer 710 covers the piezoelectric vibrator 500.

In a second step, with continued reference to FIG. 2j, a cap material layer is formed over the surface of the device wafer 100, which wraps the sacrificial layer 710 by covering the top and side surfaces of the sacrificial layer 710.

The space occupied by the sacrificial layer 710 corresponds to the internal space of the subsequently formed upper cavity. Therefore, a depth of the resulting upper cavity may be adjusted by changing a height of the sacrificial layer. It will be recognized that the depth of the upper cavity may be determined as practically required, without limiting the present invention in any sense.

The cap material layer may extend from the sacrificial layer 710 further over the back side of the device wafer 100 and thus cover the third and fourth conductive plugs 211b, 212b.

In a third step, with reference to FIGS. 2j and 2k, at least one opening 720a is formed in the cap material layer, thus resulting in the formation of the cap layer 720. The sacrificial layer 710 is exposed in the opening 720a. The sacrificial layer is then removed via the opening 720a, resulting in the formation of the upper cavity 700.

As a result, the piezoelectric vibrator 500 is enclosed in the upper cavity 700 so that the piezoelectric vibrator 500 can vibrate in the lower and upper cavities 120, 700.

Optionally, with reference to FIG. 21, the method may further include closing the opening in the cap layer 720 and thus hermetically sealing the upper cavity 700, thus enclosing the piezoelectric vibrator 500 within the upper cavity 700. Specifically, the enclosure of the upper cavity 700 may be accomplished by closing the opening with a closure plug 730.

In step S500, with reference to FIG. 2m, a semiconductor die 900 is bonded to the back side of the device wafer 100 in such a manner that the semiconductor die 900 is electrically connected to the control circuit by the second connecting structure.

In the semiconductor die, for example, a drive circuit for providing an electrical signal may be formed. The electrical signal is applied by the control circuit to the piezoelectric vibrator 500 so as to control shape change of the piezoelectric vibrator 500.

As discussed above, the conductive plugs and connecting wires in the second connecting structure are formed to lead connecting ports of the control circuit for connecting the semiconductor die to the back side of the device wafer. Prior to the bonding of the semiconductor die, the formation of the second connecting structure may further include forming contact pads on the back side of the device wafer, which are electrically connected to the conductive plugs in the second connecting structure at the bottom and to the semiconductor die at the top.

In this embodiment, the cap layer 720 extends over the whole back side of the device wafer and the cap layer 720 hence over the third and fourth conductive plugs. Thus, it will be appreciated that, in this embodiment, the contact pads are formed within, and penetrate through, cap layer. Specifically, in this embodiment, the formation of the contact pads may include the steps below.

At first, contact holes are formed in the cap layer 720 overlying the back side of the device wafer. In this embodiment, a first contact hole and a second contact hole are formed, in which the third and fourth interconnects 111b, 112b in the control circuit are exposed, respectively.

Next, a conductive material is filled in the contact holes, resulting in the formation of the contact pads, which are electrically connected to the control circuit at the bottom and are to be brought into electrical connection with the semiconductor die at the top. in this embodiment, the first and second contact pads 910, 920 are formed by filling the conductive material in the first and second contact holes. The first contact pad 910 is electrically connected to the third interconnect 111b at the bottom and to be brought into electrical connection with the semiconductor die 900 at the top. The second contact pad 920 is electrically connected to the fourth interconnect 112b at the bottom and to be brought into electrical connection with the semiconductor die 900 at the top.

The semiconductor die may be heterogeneous from the device wafer 100. That is, the semiconductor die may include a substrate made of a material different from that of the device wafer 100. For example, in this embodiment, differing from the device wafer 100 that is made of silicon, the substrate of the heterogeneous die may be formed of a Group III-V semiconductor material or a Group II-VI semiconductor material (specific examples include germanium, germanium silicon, gallium arsenide, etc.)

Optionally, with reference to FIG. 2n, a plastic encapsulation layer 800 may be formed over the device wafer 100, the plastic encapsulation layer 800 covers the semiconductor die and an external surface of the cap layer 720 outside the upper cavity 700.

It will be appreciated that the plastic encapsulation layer 800 covering the whole back side of the device wafer 100 is provided to cover and protect all the underlying structures. Exemplary materials for the plastic encapsulation layer 800 may include photoresist.

A structure for integrating a crystal resonator with a control circuit corresponding to the above method according to an embodiment will be described below with reference to FIGS. 2a to 2n. The structure includes:

a device wafer 100, the control circuit and a lower cavity 120 are formed in the device wafer 100, the lower cavity 120 having an opening at a back side of the device wafer, the control circuit optionally including interconnects, at least some of which extend to a front side of the device wafer 100;

a piezoelectric vibrator 500 including a top electrode 530, a piezoelectric crystal 520 and a bottom electrode 510, the piezoelectric vibrator 500 formed on the back side of the device wafer 100 above the lower cavity 120 and aligned with the lower cavity 120, the piezoelectric vibrator 200 optionally having peripheral edge portions residing on top edges of the lower cavity 120;

a first connecting structure formed on the device wafer 100, the first connecting structure electrically connecting both the top and bottom electrodes 530, 510 of the piezoelectric vibrator 500 to the control circuit;

a cap layer 720 formed on the back side of the device wafer 100 so as to hood the piezoelectric vibrator 500, the cap layer 720 delimiting an upper cavity together with the piezoelectric vibrator 500 and the device wafer;

a semiconductor die 900 bonded to the back side of the device wafer 100; and

a second connecting structure electrically connecting the semiconductor die 900 to the control circuit.

The semiconductor die 900 may be heterogeneous from the device wafer 100. For example, in this embodiment, differing from the device wafer 100 that is made of silicon, the substrate of the heterogeneous die may be formed of a Group III-V semiconductor material or a Group II-VI semiconductor material (specific examples include germanium, germanium silicon, gallium arsenide, etc.)

Thus, the integration of the crystal resonator with the control circuit on the same device wafer is accomplished by forming the crystal resonator through forming the lower cavity 120 in the device wafer 100 and fabricating the cap layer 720 using semiconductor processes, which encloses the piezoelectric vibrator 500 within the upper cavity 700 and thus ensures that the piezoelectric vibrator 500 can oscillate within the upper and lower cavities 700, 120. In addition, the semiconductor die bonded to the device wafer 100 can enhance performance of the crystal resonator by on-chip modulation under the control of the control circuit 110 for correcting raw deviations of the crystal resonator such as temperature and frequency drifts. Therefore, in addition to an enhanced degree of integration, the crystal resonator of the present invention fabricated using semiconductor processes is more compact in size and thus less power-consuming.

With continued reference to FIG. 2a, the control circuit may include first and second circuits 111, 112, the first and second circuits 111, 112 are electrically connected to the top and bottom electrodes of the piezoelectric vibrator 500, respectively.

Specifically, the first circuit 111 may include a first transistor, a first interconnect 111a and a third interconnect 111b. The first transistor may be buried within the device wafer 100, and the first and third interconnects 111a, 111b may be both electrically connected to the first transistor and extend to the front side of the device wafer 100. The first interconnect 111a may be electrically connected to the bottom electrode 210 and the third interconnect 111b to the semiconductor die.

The second circuit 112 may include a second transistor, a second interconnect 112a and a fourth interconnect 112b. The second transistor may be buried within the device wafer 100, and the second and fourth interconnects 112a, 112b may be both electrically connected to the second transistor and extend to the front side of the device wafer 100. The second interconnect 112a may be electrically connected to the top electrode 230 and the fourth interconnect 112b to the semiconductor die.

The first connecting structure may include a first connection and a second connection. The first connection may be connected to the first interconnect 111a and the bottom electrode 510 of the piezoelectric vibrator. The second connection may be connected to the second interconnect 112a and the top electrode 530 of the piezoelectric vibrator.

The first connection may include a first conductive plug 211a, which penetrates through the device wafer 100 so as to extend to the front side of the device wafer into electrical connection with the first interconnect at one end and to extend to the back side of the device wafer 100 into electrical connection with the bottom electrode 510 of the piezoelectric vibrator 500 at the other end.

The first connection may further include a first connecting wire 221a. In this embodiment, the first connecting wire 221a is formed on the front side of the device wafer 100 and connects the first conductive plug 211a to the first interconnect 111a. In alternative embodiments, the first connecting wire 221a may be formed on the back side of the device wafer 100 and connect the first conductive plug to the bottom electrode.

In this embodiment, the bottom electrode 510 is formed on the back side of the device wafer 100 around the lower cavity 120 and has an extension that laterally extends beyond the piezoelectric crystal 520 over the first conductive plug 211a, thus bringing the bottom electrode 210 into electrical connection with the first interconnect 111a in the first circuit 111.

The second connection may include a second conductive plug 212a, the second conductive plug 212a penetrates through the device wafer 100 so as to extend to the front side of the device wafer 100 into electrical connection with the second interconnect at one end and to extend to the back side of the device wafer 100 into electrical connection with the top electrode 530 of the piezoelectric vibrator 500 at the other end.

The second connection may further include a second connecting wire 222a. In this embodiment, the second connecting wire 222a is formed on the front side of the device wafer 100 and connects the second conductive plug 212a to the second interconnect 112a. In alternative embodiments, the second connecting wire 222a may be formed on the back side of the device wafer 100 and connect the second conductive plug to the top electrode.

The second connection may further include a fifth conductive plug 610 and an interconnecting wire. The fifth conductive plug may be formed on the back side of the device wafer 100 and connected at the bottom to the second conductive plug 212a. The interconnecting wire may cover the top electrode 530 at one end and overlap at least part of, and thus come into electrical connection with, the fifth conductive plug at the other end. It will be recognized that the fifth conductive plug also functions to support the interconnecting wire.

Alternatively, the second connection may include only the fifth conductive plug. In this case, the fifth conductive plug may be electrically connected to the top electrode 530 at one end and to the second conductive plug 212a at the other end. For example, the top electrode may extend beyond the piezoelectric crystal over the end of the fifth conductive plug.

The second connecting structure may include conductive plugs and connecting wires. The conductive plugs in the second connecting structure may extend through the device wafer 100 to the front side of the device wafer 100 at one end and to the back side of the device wafer 100 at the other end. The ends of the conductive plugs reaching the back side of the device wafer 100 may be electrically connected to the semiconductor die 900. The connecting wires may be formed on the front side of the device wafer 100 and connect the conductive plugs to the control circuit.

In this embodiment, the conductive plugs in the second connecting structure may include a third conductive plug 211b and a fourth conductive plugs 212b, and the connecting wires in the second connecting structure may include a first connecting wire 221b and a second connecting wire 222b. The third connecting wire 221b may connect the third conductive plug 211b to the third interconnect 111b, and the fourth connecting wire 222b may connect the fourth conductive plug 212b to the fourth interconnect 112b.

Optionally, the second connecting structure may further include contact pads, which are so formed on the back side of the device wafer as to be electrically connected to the conductive plugs in the second connecting structure at the bottom and to semiconductor die at the top.

With continued reference to FIG. 2n, in this embodiment, the cap layer 720 may extend from edges of the upper cavity 120 over the surface of the device wafer 100, and the semiconductor die 900 may be bonded to the cap layer 720.

Accordingly, in this embodiment, the contact pads may penetrate through the cap layer 720 so that they are electrically connected to the conductive plugs at the bottom and to the semiconductor die 900 at the top.

In this embodiment, the contact pads in the second connecting structure may include a first contact pad 910 and a second contact pad 920. The first contact pad 910 may be electrically connected to the third conductive plug 211b at the bottom and to the semiconductor die 900 at the top. The second contact pad 920 may be electrically connected to the fourth conductive plug 212b at the bottom and to the semiconductor die 900 at the top.

With continued reference to FIG. 2n, in this embodiment, the device wafer 100 includes a substrate wafer and a. dielectric layer 100B. The first and second transistors may be both formed on the substrate wafer, and the dielectric layer 100B may reside on the substrate wafer and thus cover both the first and second transistors. The third, first, fourth and second interconnects may be all formed in the dielectric layer 100B and extend up to the surface of the dielectric layer away from the substrate wafer.

The crystal resonator may further include a plastic encapsulation layer 800 formed on the back side of the device wafer 100, the plastic encapsulation layer 800 covers both the semiconductor die 900 and an external surface of the cap layer 720 outside the upper cavity 120. In other words, the plastic encapsulation layer 800 covers all the structures formed on the back side of the device wafer, thus providing protection to the structures underlying the plastic encapsulation layer 800.

In this embodiment, the lower cavity 120 extends through the device wafer 100 and thus has another opening at the front side of the device wafer. Accordingly, a cap substrate may be optionally bonded to the front side of the device wafer to close the opening of the lower cavity present at the front side of the device wafer. The cap substrate may be composed of, for example, a silicon wafer.

In summary, in the method of the present invention, the crystal resonator, the control circuit and the semiconductor die can be integrated on the same substrate. This helps in on-chip modulation of the crystal resonator's parameters (e.g., for correcting raw deviations such as temperature and frequency drifts) and thus enhances its performance.

Moreover, compared with traditional crystal resonators (e.g., surface-mount ones), in addition to being able to integrate with other semiconductor components with a higher degree of integration, the crystal resonator of the present invention fabricated using planar fabrication processes is more compact in size and thus less power-consuming.

The description presented above is merely that of a few preferred embodiments of the present invention without limiting the scope thereof in any sense. Any and all changes and modifications made by those of ordinary skill in the art based on the above teachings fall within the scope as defined in the appended claims.

1. A method for integrating a crystal resonator with a control circuit, comprising:
providing a device wafer having the control circuit formed therein;
forming a lower cavity in the device wafer, the lower cavity having an opening formed at a back side of the device wafer;
forming a piezoelectric vibrator comprising a top electrode, a piezoelectric crystal and a bottom electrode on the back side of the device wafer, the piezoelectric vibrator arranged in alignment with the lower cavity, and forming a first connecting structure electrically connecting the top and bottom electrodes of the piezoelectric vibrator to the control circuit;
forming a cap layer over the back side of the device wafer, which hoods the piezoelectric vibrator and delimits an upper cavity of the crystal resonator together with the piezoelectric vibrator and the device wafer; and
bonding a semiconductor die to the back side of the device wafer and forming a second connecting structure electrically connecting the semiconductor die to the control circuit.

2. The method for integrating a crystal resonator with a control circuit of claim 1, wherein the device wafer comprises a substrate wafer and a dielectric layer on the substrate wafer, and wherein the substrate wafer is a silicon-on-insulator substrate comprising a base layer, a buried oxide layer and a top silicon layer stacked in sequence from the back side to the front side.

3. (canceled)

4. The method for integrating a crystal resonator with a control circuit of claim 1, wherein the formation of the lower cavity comprises: etching the device wafer from the front side of the device wafer, thereby resulting in the formation of the lower cavity of the crystal resonator; thinning the device wafer from the back side of the device wafer, thereby exposing the lower cavity; and bonding a cap substrate to the front side of the device wafer so that the cap substrate covers and closes the opening of the lower cavity at the front side of the device wafer, or
wherein the formation of the lower cavity comprises etching the device wafer from the back side of the device wafer, thereby resulting in the formation of the lower cavity of the crystal resonator,
wherein the device wafer comprises a silicon-on-insulator substrate comprising a base layer, a buried oxide layer and a top silicon layer stacked in sequence from the back side to the front side, and
wherein the method further comprises, prior to forming the lower cavity by etching the device wafer from the back side of the device wafer, removing the base layer and the buried oxide layer, and forming the lower cavity by etching the device wafer from the back side thereof comprises forming the lower cavity by etching the top silicon layer.

5. (canceled)

6. The method for integrating a crystal resonator with a control circuit of claim 1, wherein the formation of the piezoelectric vibrator comprises:
forming the bottom electrode at a predetermined location on the back side of the device wafer;
bonding the piezoelectric crystal to the bottom electrode; and
forming the top electrode on the piezoelectric crystal, or comprises:
forming the top and bottom electrodes of the piezoelectric vibrator on the piezoelectric crystal; and bonding the top and bottom electrodes and the piezoelectric crystal as a whole to the back side of the device wafer,
wherein the formation of the bottom electrode comprises a vapor deposition process or a thin-film deposition process, and wherein the formation of the top electrode comprises a vapor deposition process or a thin-film deposition process.

7. (canceled)

8. The method for integrating a crystal resonator with a control circuit of claim 1, wherein the control circuit comprises a first interconnect and a second interconnect and the connecting structure comprises a first connection and a second connection,
the first connection connecting the first interconnect to the bottom electrode of the piezoelectric vibrator, the second connection connecting the second interconnect to the top electrode of the piezoelectric vibrator.

9. The method for integrating a crystal resonator with a control circuit of claim 8, wherein the first connection is formed prior to the formation of the bottom electrode, and wherein:
the first connection comprises a first conductive plug in the device wafer, two ends of the first conductive plug electrically connected respectively to the first interconnect and the bottom electrode; or
the first connection comprises a first conductive plug in the device wafer and a first connecting wire on the back side of the device wafer, the first connecting wire electrically connected to one end of the first conductive plug, the first conductive plug electrically connected at the other end to the first interconnect, the first connecting wire electrically connected to the bottom electrode; or
the first connection comprises a first conductive plug in the device wafer and a first connecting wire on the front side of the device wafer, the first connecting wire electrically connected to one end of the first conductive plug, the first conductive plug electrically connected at the other end to the bottom electrode, the first connecting wire electrically connected to the first interconnect.

10. The method for integrating a crystal resonator with a control circuit of claim 9, wherein the formation of the first connection comprising the first conductive plug and the first connecting wire on the front side of the device wafer comprises:
forming a first connecting hole by etching the device wafer from the front side of the device wafer;
filling a conductive material in the first connecting hole, thus resulting in the formation of the first conductive plug;
forming the first connecting wire on the front side of the device wafer, the first connecting wire connecting the first conductive plug to the first interconnect; and
thinning the device wafer from the back side of the device wafer so that the first conductive plug is exposed and is available for electrical connection to the bottom electrode of the piezoelectric vibrator, or wherein
the formation of the first connection comprising the first conductive plug and the first connecting wire on the front side of the device wafer comprises:
forming the first connecting wire on the front side of the device wafer, the first connecting wire electrically connected to the first interconnect;
thinning the device wafer from the back side of the device wafer and forming a first connecting hole by etching the device wafer from the back side of the device wafer, the first connecting hole extending through the device wafer so that the first connecting wire is exposed in the first connecting hole; and
filling a conductive material in the first connecting hole, thus resulting in the formation of the first conductive plug, the first conductive plug connected at one end to the first connecting wire, the other end of the first conductive plug available for electrical connection to the bottom electrode of the piezoelectric vibrator, or wherein
the formation of the first connection comprising the first conductive plug and the first connecting wire on the back side of the device wafer comprises:
forming a first connecting hole by etching the device wafer from the front side of the device wafer;
filling a conductive material in the first connecting hole, thus resulting in the formation of the first conductive plug, the first conductive plug electrically connected to the first interconnect;
thinning the device wafer from the back side of the device wafer so that the first conductive plug is exposed; and
forming the first connecting wire on the back side of the device wafer, the first connecting wire connected at one end to the first conductive plug, the other end of the first connecting wire available for electrical connection to the bottom electrode, or wherein
the formation of the first connection comprising the first conductive plug and the first connecting wire on the back side of the device wafer comprises:
thinning the device wafer from the back side of the device wafer and forming a first connecting hole by etching the device wafer from the back side of the device wafer,
filling a conductive material in the first connecting hole, thus resulting in the formation of the first conductive plug, the first conductive plug electrically connected at one end to the first interconnect; and
forming the first connecting wire on the back side of the device wafer, the first connecting wire connected at one end to the other end of the first conductive plug, the other end of the first connecting wire available for electrical connection to the bottom electrode, or wherein
the bottom electrode is formed on the back side of the device wafer so as to extend beyond the piezoelectric crystal to come into electrical connection with the first connection.

11-12. (canceled)

13. The method for integrating a crystal resonator with a control circuit of claim 8, wherein the second connection is formed prior to the formation of the top electrode, and wherein:
the second connection comprises a second conductive plug in the device wafer, two ends of the second conductive plug configured to be electrically connected respectively to the second interconnect and the top electrode; or
the second connection comprises a second conductive plug in the device wafer and a second connecting wire on the back side of the device wafer, the second connecting wire electrically connected to one end of the second conductive plug, the second conductive plug electrically connected at the other end to the second interconnect, the second connecting wire electrically connected to the top electrode; or
the second connection comprises a second conductive plug in the device wafer and a second connecting wire on the front side of the device wafer, the second connecting wire electrically connected to one end of the second conductive plug, the second conductive plug electrically connected at the other end to the top electrode, the second connecting wire electrically connected to the second interconnect.

14. The method for integrating a crystal resonator with a control circuit of claim 13, wherein the formation of the second connection comprising the second conductive plug and the second connecting wire on the front side of the device wafer comprises:
forming a second connecting hole by etching the device wafer from the front side of the device wafer;
filling a conductive material in the second connecting hole, thus resulting in the formation of the second conductive plug;
forming the second connecting wire on the front side of the device wafer, the second connecting wire connecting the second conductive plug to the second interconnect; and
thinning the device wafer from the back side of the device wafer so that the second conductive plug is exposed and is available for electrical connection to the top electrode of the piezoelectric vibrator, or wherein
the formation of the second connection comprising the second conductive plug and the second connecting wire on the front side of the device wafer comprises:
forming the second connecting wire on the front side of the device wafer, the second connecting wire electrically connected to the second interconnect;
thinning the device wafer from the back side of the device wafer and forming a second connecting hole by etching the device wafer from the back side of the device wafer, the second connecting hole extending through the device wafer so that the second connecting wire is exposed in the second connecting hole; and
filling a conductive material in the second connecting hole, thus resulting in the formation of the second conductive plug, the second conductive plug connected at one end to the second connecting wire, the other end of the second conductive plug available for electrical connection to the top electrode of the piezoelectric vibrator, or wherein
the formation of the second connection comprising the second conductive plug and the second connecting wire on the back side of the device wafer comprises:
forming a second connecting hole by etching the device wafer from the front side of the device wafer;
filling a conductive material in the second connecting hole, thus resulting in the formation of the second conductive plug, the second conductive plug electrically connected to the second interconnect;
thinning the device wafer from the back side of the device wafer so that the second conductive plug is exposed; and
forming the second connecting wire on the back side of the device wafer, the second connecting wire connected at one end to the second conductive plug, the other end of the second connecting wire available for electrical connection to the top electrode, or wherein
the formation of the second connection comprising the second conductive plug and the second connecting wire on the back side of the device wafer comprises:
thinning the device wafer from the back side of the device wafer and forming a second connecting hole by etching the device wafer from the back side of the device wafer,
filling a conductive material in the second connecting hole, thus resulting in the formation of the second conductive plug, the second conductive plug electrically connected at one end to the second interconnect; and
forming the second connecting wire on the back side of the device wafer, the second connecting wire connected at one end to the other end of the second conductive plug, the other end of the second connecting wire available for electrical connection to the top electrode, or wherein
the formation of the second connection further comprises:
forming a plastic encapsulation layer on the back side of the device wafer; and
forming a through hole in the plastic encapsulation layer and filling a conductive material in the through hole, thus resulting in the formation of a fifth conductive plug, the fifth conductive plug has a bottom electrically connected to the second conductive plug, the fifth conductive plug has a top exposed from the plastic encapsulation layer, and
wherein the top electrode is so formed that it extends beyond the piezoelectric crystal over the fifth conductive plug, thus coming into electrical connection with the fifth conductive plug; or subsequent to the formation of the top electrode, an interconnecting wire is formed on the plastic encapsulation layer, the interconnecting wire extending over the top electrode at one end and over the fifth conductive plug at the other end, followed by removal of the plastic encapsulation layer.

15-16. (canceled)

17. The method for integrating a crystal resonator with a control circuit of claim 1, wherein the formation of the cap layer delimiting the upper cavity comprises:
forming a sacrificial layer on the back side of the device wafer, which covers the piezoelectric vibrator;
forming a cap material layer over the back side of the device wafer, which warps the sacrificial layer by covering top and side surfaces of the sacrificial layer; and
forming at least one opening in the cap material layer, thus resulting in the formation of the cap layer and removing the sacrificial layer via the opening in which the sacrificial layer is exposed, thus resulting in the formation of the upper cavity,
after forming the upper cavity, the method further comprising closing the opening in the cap layer to close the upper cavity and thereby enclosing the piezoelectric vibrator within the upper cavity.

18. (canceled)

19. The method for integrating a crystal resonator with a control circuit of claim 1, wherein the formation of the second connecting structure comprises:
forming connecting holes in the device wafer by etching the device wafer from the front side thereof;
forming conductive plugs by filling a conductive material in the connecting holes;
forming connecting wires on the front side of the device wafer, which connect the respective conductive plugs to the control circuit; and
thinning the device wafer from the back side thereof until the conductive plugs are exposed for electrical connection with the semiconductor die, or wherein
the formation of the second connecting structure comprises:
forming connecting wires on the front side of the device wafer, which are electrically connected to the control circuit;
etching the device wafer from the back side thereof so that connecting holes are formed therein, which extend through the device wafer, and in which the respective connecting wires are exposed; and
filling a conductive material in the connecting holes so that conductive plugs are formed, which are connected to the respective connecting wires at one end and ready for electrical connection with the semiconductor die at the other end.

20. (canceled)

21. The method for integrating a crystal resonator with a control circuit of claim 19, wherein the formation of the second connecting structure further comprises:
forming contact pads on the back side of the device wafer, the contact pads having bottoms electrically connected to the conductive plugs and tops electrically connected to the semiconductor die.

22. The method for integrating a crystal resonator with a control circuit of claim 1, further comprising, subsequent to the bonding of the semiconductor die,
forming a plastic encapsulation layer over the back side of the device wafer, which covers the semiconductor die and an external surface of the cap layer outside the upper cavity.

23. A structure for integrating a crystal resonator with a control circuit, comprising:
a device wafer in which the control circuit and a lower cavity are formed, the lower cavity having an opening at a back side of the device wafer;
a piezoelectric vibrator comprising a bottom electrode, a piezoelectric crystal and a top electrode, the piezoelectric vibrator formed on the back side of the device wafer in alignment with the lower cavity;
a first connecting structure formed on the device wafer, the first connecting structure electrically connecting the top and bottom electrodes of the piezoelectric vibrator to the control circuit;
a cap layer formed on the back side of the device wafer, the cap layer hooding the piezoelectric vibrator, the cap layer delimiting an upper cavity together with the piezoelectric vibrator and the device wafer;
a semiconductor die bonded to the back side of the device wafer; and
a second connecting structure electrically connecting the semiconductor die to the control circuit.

24. The structure for integrating a crystal resonator with a control circuit of claim 23, wherein the control circuit comprises a first interconnect and a second interconnect and the connecting structure comprises a first connection and a second connection,
the first connection connecting the first interconnect to the bottom electrode of the piezoelectric vibrator, the second connection connecting the second interconnect to the top electrode of the piezoelectric vibrator,
wherein the first connection comprises a first conductive plug, which extends through the device wafer so that one end of first conductive plug is located at the front side of the device wafer and electrically connected to the first interconnect and the other end of the first conductive plug is located at the back side of the device wafer and electrically connected to the bottom electrode of the piezoelectric vibrator.

25. (canceled)

26. The structure for integrating a crystal resonator with a control circuit of claim 24, wherein the first connection further comprises a first connecting wire, and wherein
the first connecting wire is formed on the front side of the device wafer and connects the first conductive plug to the first interconnect, or
the first connecting wire is formed on the back side of the device wafer and connects the first conductive plug to the bottom electrode.

27. The structure for integrating a crystal resonator with a control circuit of claim 24, wherein the bottom electrode is formed on the back side of the device wafer so as to extend beyond the piezoelectric crystal and come into electrical connection with the first conductive plug,
wherein the second connection comprises a second conductive plug, which extends through the device wafer so that one end of the second conductive plug is located at the front side of the device wafer and electrically connected to the second interconnect and the other end of the second conductive plug is located at the back side of the device wafer and electrically connected to the top electrode of the piezoelectric vibrator.

28. (canceled)

29. The structure for integrating a crystal resonator with a control circuit of claim 27, wherein the second connection further comprises a second connecting wire, and wherein
the second connecting wire is formed on the front side of the device wafer and connects the second conductive plug to the second interconnect, or
the second connecting wire is formed on the back side of the device wafer and connects the second conductive plug to the top electrode, or wherein
the second connection further comprises a fifth conductive plug formed on the back side of the device wafer, the fifth conductive plug electrically connected to the top electrode at one end and to the second conductive plug at the other end, or wherein
the second connection further comprises:
a fifth conductive plug formed on the back side of the device wafer, the fifth conductive plug having a bottom electrically connected to the second conductive plug; and
an interconnecting wire, which covers the top electrode at one end and covers a top of the fifth conductive plug at the other end.

30-31. (canceled)

32. The structure for integrating a crystal resonator with a control circuit of claim 23, wherein the second connecting structure comprises:
conductive plugs, each extending through the device wafer so that one end of the conductive plugs is located at the front side of the device wafer and the other end of the conductive plugs is located at the back side of the device wafer and electrically connected to the semiconductor die; and
connecting wires formed on the front side of the device wafer, the connecting wires connecting the conductive plugs to the control circuit; and
contact pads, which have bottoms electrically connected to the conductive plugs and tops electrically connected to the semiconductor die.

33. (canceled)

34. The structure for integrating a crystal resonator with a control circuit of claim 23, wherein at least one opening is formed in the cap layer and is closed with a closure plug filled therein, thereby enclosing the upper cavity, and/or wherein
the structure further comprises a plastic encapsulation layer formed on the back side of the device wafer, the plastic encapsulation layer covering the semiconductor die and an external surface of the cap layer outside the upper cavity.

35. (canceled)
